(19) United States
(12) Patent Application Publication
(10) Pub. No.: US 2019/0002735 A1
(43) Pub. Date: Jan. 3, 2019

(54) COUPLING OPTOELECTRONIC COMPONENTS USING TEMPLATED PRESSURE SENSITIVE ADHESIVE FILMS

(71) Applicant: Intel Corporation, Santa Clara, CA (US)

(72) Inventors: Mohit Gupta, Chandler, AZ (US); Anna M. Prakash, Chandler, AZ (US); Vladimir Malamud, Hedera (IL); Mark Saltas, Buckeye, AZ (US); Ziv Belman, Yokneam Ilit (IL)

(73) Assignee: Intel Corporation, Santa Clara, CA (US)

(21) Appl. No.: 15/637,960

(22) Filed: Jun. 29, 2017

(51) Int. Cl. C09J 7/02; H01B 1/02; H01L 23/36; C09J 1/00

(52) U.S. Cl. CPC C09J 7/0207; C09J 1/00; H01L 23/36; H01B 1/02

(57) ABSTRACT

Aspects of the embodiments are directed to an optoelectronic device that includes one or more pressure sensitive adhesives to secure components during an assembly process. The optoelectronic device includes an electromagnetic interference/radio frequency interference shield. The shield can include an aperture for permitting light to enter a photodetector. An infrared filter can be secured to the shield using a pressure sensitive adhesive (PSA) film. The PSA film can be a templated film that is double sided. A PSA film can also be used to secure the shield to the printed circuit board (PCB) of the optoelectronic device. To promote electromagnetic conduction between the shield and the PCB, the PSA film can include additives. Aspects of the embodiments are directed to methods for assembling the optoelectronic device by picking and placing a PSA film and applying a pressure to certain components to activate the PSA film adhesion.

### TECHNICAL FIELD

This disclosure pertains to using a pressure sensitive adhesive for optoelectronic packaging assembly.

### BACKGROUND

In opto-electronic packages, seamless transition of photons/light into the detectors and photo diodes is critical. In some optoelectronic devices, the compound parabolic concentrator is coupled to the detector. This assembly is encased inside the electromagnetic interference/radio-frequency interference (EMI/RFI) shield with infrared (IR) filters.

### BRIEF DESCRIPTION OF THE DRAWINGS

FIG. 1 is a schematic diagram of an optoelectronic device that includes a pressure sensitive adhesive in accordance with embodiments of the present disclosure.

FIG. 2 is a schematic diagram of a cross sectional view of photodetector in accordance with embodiments of the present disclosure.

FIG. 3A is a schematic diagram of perspective view of an example photodetector shield in accordance with embodiments of the present disclosure.

FIG. 3B is a schematic diagram of a top-down view of an example photodetector shield in accordance with embodiments of the present disclosure.

FIG. 3C is a schematic diagram of a perspective view of another example photodetector shield in accordance with embodiments of the present disclosure.

FIG. 3D is a schematic diagram of a top-down view of the other example photodetector shield in accordance with embodiments of the present disclosure.

FIG. 4 is a schematic diagram of an exploded view of a photodetector shield and a pressure sensitive adhesive in accordance with embodiments of the present disclosure.

FIG. 5 is a process flow diagram for assembling an optoelectronic device with a pressure sensitive adhesive in accordance with embodiments of the present disclosure.

FIG. 6A is a schematic diagram of an optical projector in accordance with embodiments of the present disclosure.

FIG. 6B is a schematic diagram of a sensor in accordance with embodiments of the present disclosure.

FIG. 7 is a computing device built in accordance with an embodiment of the disclosure.

Figures may not be drawn to scale.

### DETAILED DESCRIPTION

Described herein are systems and methods of using a pressure sensitive adhesive (PSA) film for optoelectronic packaging assembly. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

Optoelectronic components can be secured using a dispensed or spray-on type of adhesive, which are typically heat or UV curable. For example, an IR filter can be attached to an EMI/RFI shield using liquid dispensable adhesives. With the liquid dispense process, it was difficult to maintain tight bond line thickness (BLT) requirements and tight keep out zone (KOZ) requirements, which led to bleeding of the adhesive onto the lens. This bleeding can cause lens contamination and can affect overall performance and sensor efficiency. Techniques used to control the spread of adhesives used to secure optoelectronic components include controlling the amount and viscosity of the adhesive. This control can be difficult considering that a full seal is required between the shields and optical detectors to prevent the extra stray light from getting in to the optical assembly and/or light being lost from being received into the detector. Additionally, adhesives should not wrap around the top of the IR filter.

This disclosure describes using a preform of double sided pressure sensitive adhesive (PSA) film as the adhesive for optoelectronic devices, and in particular, around the window on top of a EMI/RFI shield. Suitable PSA films can be used that have good adhesion to both the EMI/RFI shield the IR filter. This will cause easier processing (e.g., pick and place (PnP)) of the IR filter on top of the EMI/RFI shield, higher throughput, less mess (no more liquid dispensing), and less waste. Additionally, PSA films can facilitate achieving the high PnP precision required in attaching optoelectronic components to ensure no misalignment and loss of signal.

Using a PSA film adhesive also eliminates thermal curing requirements that could damage the opto-electronic components that are sensitive to temperature exposure. Additionally, the PSA film can include additives, such as additives that allow the adhesive to be electrically, thermally, and or magnetically conductive using conductive filler. Additives can also cause the adhesive to facilitate electromagnetic interference (EMI) shielding.

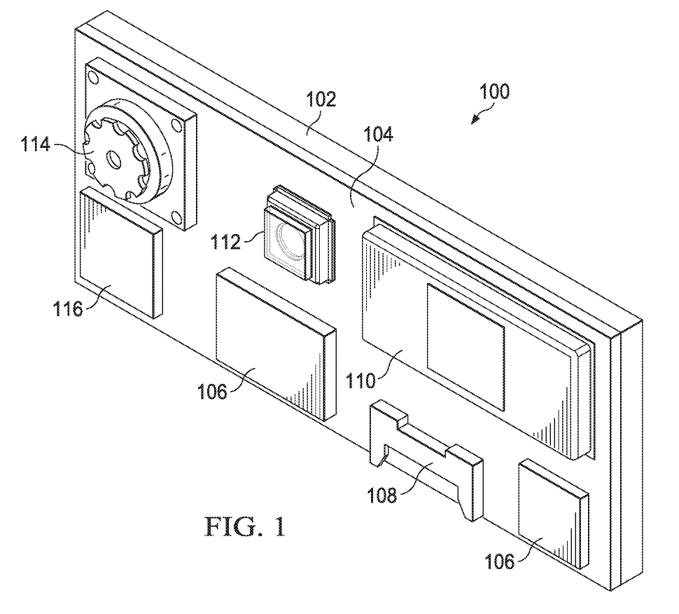

FIG. 1 is a schematic diagram of an optoelectronic device 100 that includes a pressure sensitive adhesive to couple optical components in accordance with embodiments of the present disclosure. The optoelectronic device 100 can include a chassis 102. The chassis 102 can secure one or more electronic and optoelectronic components. The chassis 102 can also secure a printed circuit board (PCB) 104 (also referred to as a main board 104). The PCB 104 can mechanically secure circuit components, such as ASICs 106, a power/signal interface 108, an optical projector 110, and a photodetector 112. The PCB 104 can provide mechanical and electrical connectivity for one or more of the electrical components. The chassis 102 can also secure a camera 114 and an image signal processor 116.

The optoelectronic device 100 can be formed by a pick and place processing technique. For example, the ASICs 106 can be placed onto the main board 104 by a pick and place technique, such as surface mount technology. The ASICs 106 can be electrically and mechanically coupled to the main board 104 by a solder process.

Some components of the optoelectronic device 100 cannot be coupled by a solder process, and may be sensitive to high temperature processes, such as high temperature curing.

The photodetector 112 can include an EMI/RFI shield can be affixed to the PCB 104 by a pressure sensitive adhesive (PSA). The EMI/RFI shield can be affixed to the PCB 104 by a PSA that includes a conductive filler to promote electromagnetic conduction. The photodetector 112 can include an IR filter that is affixed to the EMI/RFI shield by a PSA. The PSAs can be double sided to promote adhesion between two components.

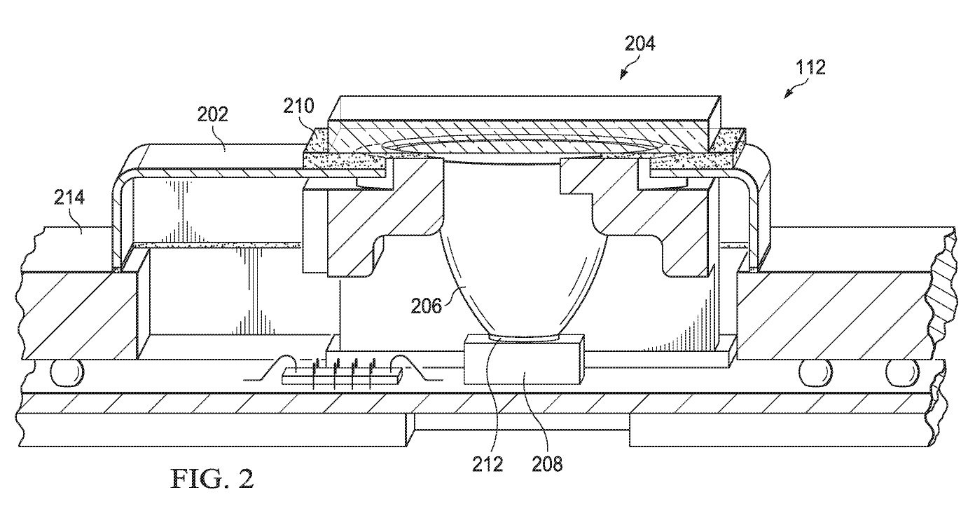

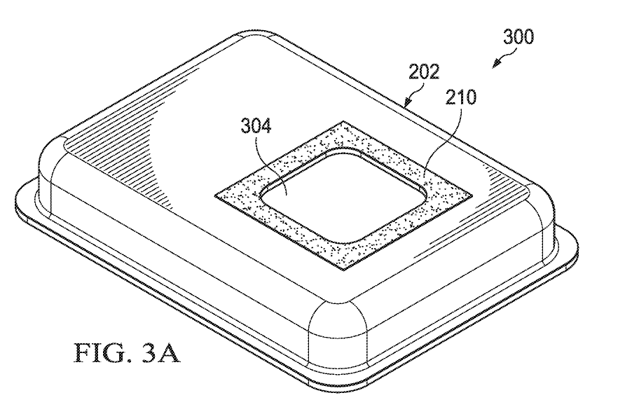

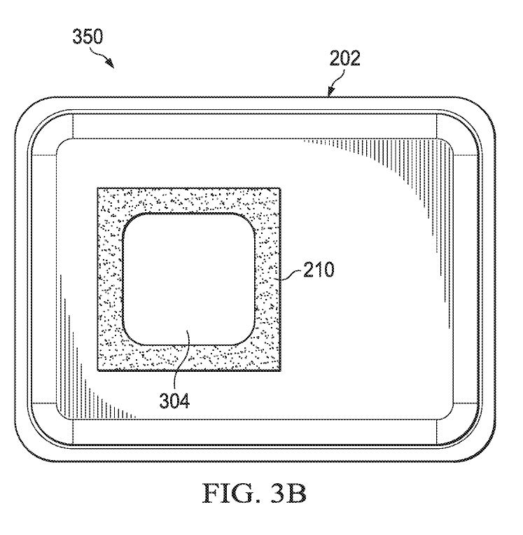

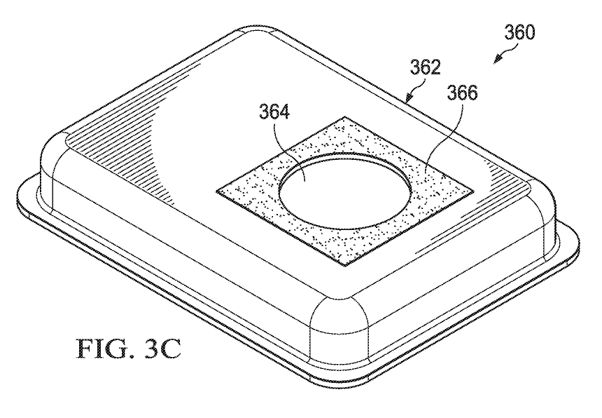

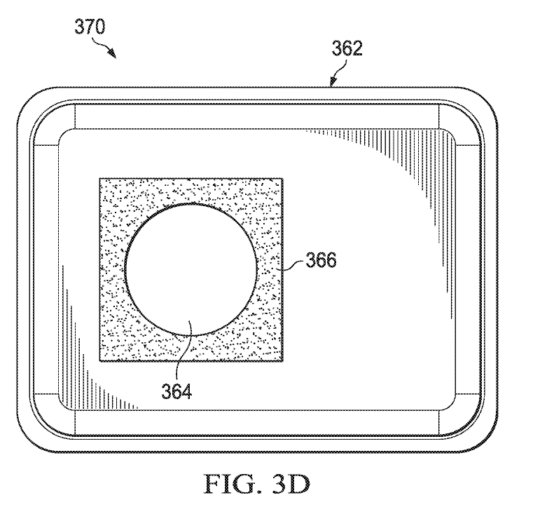

As an example, FIG. 2 is a schematic diagram of a cross sectional view of photodetector 112 in accordance with embodiments of the present disclosure. The photodetector 112 can include an EMI/RFI shield 202. The EMI/RFI shield 202 can include an aperture 218 (shown absent the IR filter in FIGS. 3A-3D) for permitting light to enter the lens 206 and photodiode 208.

The aperture 218 can be covered by an IR filter 204. The IR filter 204 can filter light entering the aperture 218. The light can be focused by a lens 206 towards a photodetector, such as avalanche photodiode (APD) 208.

The IR filter 204, the lens 206, and the APD 208 can each be considered optical components for the purposes of this disclosure. These optical components can be mechanically secured using a pressure sensitive adhesive (PSA) film that is applied during the pick and place procedure. Example PSA materials can include acrylics made using methyl acrylate, butyl acrylate, 2ethylhexyl acrylate. The PSA can include a double-sided adhesive. The PSA film can be a templated film that can be picked and placed onto various surfaces during a pick-and-place manufacturing/assembly process. The PSA film can be templated to have a shape and size to conform to any surface or surfaces. The PSA film can be activated by a pressure, the value of which can depend on the components being assembled and the pick-and-place process used.

For example, a PSA film 210 can be placed on top of EMI/RFI shield 202. The PSA film 210 can secure the IR filter 204 to the EMI/RFI shield 202. The PSA film 210 can be a templated film that is shaped to have an open space through its center so that the film does not cover the aperture 218. The open space in the PSA film 210 can act as an optical window for light transmission through the IR filter 204 to the lens 206. PSA film 210 is chosen to promote good adhesion to both the EMI/RFI shield 202 and the IR filter 204. The PSA film 210 provides a full seal between the IR filter 204 and the EMI/RFI shield 202.

By using a film-based PSA film, the IR filter can be placed (e.g., by a pick and place or SMT process) on top of the EMI/RFI shield 202. Using a film that is placed can lead to higher optical throughput. For example, the film-based PSA film that has a gap for optical transmission means that the IR filter can be secured to the EMI/RFI shield 202 without excess glue from encroaching onto the optical transmission path. Similarly, the use of a film-based PSA film that is placed onto the EMI/RFI shield 202 results in less mess from overflow and less waste from imprecise amount of liquid glue being applied to the cover. Also, a film adhesive will provide uniform bond line thickness. Additionally, the use of a film-based PSA film removes the need for a thermal cure of the liquid glue. By avoiding thermal curing, the optical components that are sensitive to high temperatures can be protected.

A PSA film 212 can be placed between the lens 206 and the APD 208. The PSA film 212 can secure the lens 206 and the APD 208. The PSA film 212 can also act as an optical window for light transmission from the lens 206 and the APD 208.

The EMI/RFI shield 202 can be coupled to the PCB 214 by a conductive PSA 216. The PSA 216 can include additives for promoting electromagnetic conduction through the EMI/RFI shield 202 to the PCB 214. Such additives can include, but are not limited to, copper, silver, nickel, aluminum, or other metallic powders/metal flakes.

The PSA film can include one or more additives. Additives can provide additional characteristics beyond adhesion and optical transparency, expanding the use of PSA films for securing other components to the optoelectronic device 100.

For example, the PSA film can include a conductive filler that can facilitate adhesion and electrical conductivity between the RF shield (by EMI/RFI shield 202) and the chassis 102. The EMI/RFI shield 202 can serve as an EMI/RFI shield for the internal components of the photodetector 112, such as the APD 208. The PSA film additives for facilitating conductivity include, but are not limited to, copper, silver, nickel, aluminum, or other metallic powders/metal flakes.

In some embodiments, an additive can also be used for enhancing EMI shielding. The PSA film that includes EMI shielding additives can be used to shield sensitive electronic devices such as the APD 208 from EMI or RF interferences produced by internal or external sources. Examples of EMI shielding additives include nickel graphite and/or carbon fibers, as well as other types of EMI shielding additives.

In embodiments, the PSA film can include magnetic additives. A PSA film that includes magnetic additives can be used to secure magnetic elements to a projector housing through a pick and place process. Examples of magnetic additives include, but are not limited to, magnetite, ferrit, Sendust (FeAlSi), as well as other magnetic additives.

In embodiments, the PSA film can include additives that enhance thermal conduction. For example, the PSA additive that includes thermal conduction additives can be used for securing lasers and/or laser drivers to the main board 104 or to the chassis 102. The PSA film that includes thermal conduction additives can assist in cooling lasers, laser drivers, and other higher temperature components. Examples of thermally conductive additives includes copper, silver, aluminum, zinc oxide, boron nitride, aluminum oxide, nano-particles, etc.

FIG. 3A is a schematic diagram 300 of perspective view of an example photodetector EMI/RFI shield 302 in accordance with embodiments of the present disclosure. FIG. 3B is a schematic diagram 350 of a top-down view of an example photodetector EMI/RFI shield 302 in accordance with embodiments of the present disclosure. The photodetector EMI/RFI shield 302 can include an aperture 304. The aperture 304 can permit light to enter the lens 206 (shown in FIG. 2). The aperture 304 can be covered by the IR filter 204 (not shown in FIGS. 3A-3B). The PSA 306 can be placed around the aperture 304. The PSA 306 can be templated to fit around the aperture 304, which in FIG. 3A-B is a square shaped aperture. The PSA 306 is templated to be large enough so that the IR filter can be placed on top of the PSA 306 to create a seal between the IR filter and the PSA 306.

FIG. 3C is a schematic diagram of a perspective view 360 of another example EMI/RFI shield 362 in accordance with embodiments of the present disclosure. FIG. 3D is a schematic diagram of a top-down view 370 of the other example EMI/RFI shield 362 in accordance with embodiments of the present disclosure. The photodetector EMI/RFI shield 362 can include an aperture 364. In FIGS. 3C-D, the EMI/RFI shield 362 has a circular aperture 364. The aperture 364 can permit light to enter the lens 206 (shown in FIG. 2). The aperture 364 can be covered by the IR filter 204 (not shown in FIGS. 3A-3B). The PSA 366 can be placed around the aperture 364. The PSA can be templated to fit around the aperture 364, which is shown to be circular in FIGS. 3C-3D, as opposed to more square-shaped in FIGS. 3A-B. The PSA 366 is templated to be large enough so that the IR filter 204 can be placed on top of the PSA 366 to create a seal between the IR filter 204 and the PSA 366.

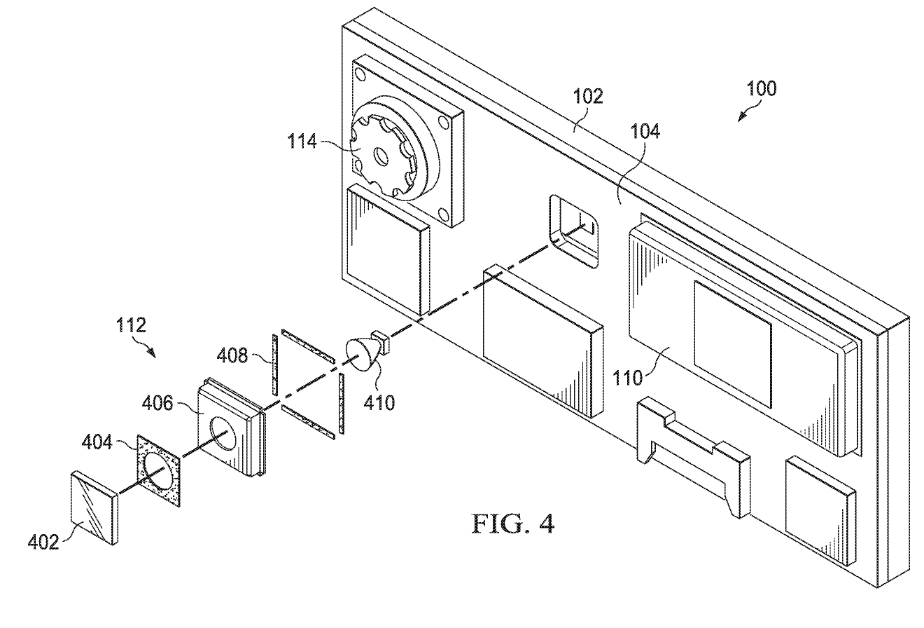

FIG. 4 is a schematic diagram of an exploded view of a photodetector shield in accordance with embodiments of the present disclosure. FIG. 4 is similar to FIG. 1. In FIG. 4, the photodetector 112 is shown exploded, to illustrate the PSA 404 that is used to secure the IR filter 402 to the EMI/RFI shield 406. Also shown in FIG. 4 is PSA 408 that can be used to secure the EMI/RFI shield 406 to the PCB 104. The PSA 408 are templated to fit under each leg of the EMI/RFI shield 406. The PSA 408 can include a conductive filler to promote EMI/RFI shielding through the PCB 104, similar to PSA 216 shown in FIG. 2.

The exploded view of the photodetector 112 illustrates the IR filter 402 that is secured to the EMI/RFI shield 406 by a double sided and templated PSA 404. PSA 404 is templated to include a circular opening through the center to accommodate the circular opening in the EMI/RFI shield 406. The lens 410 is also shown. The lens 410 can be affixed to the avalanche photodiode, for example, by a PSA (not shown in FIG. 4).

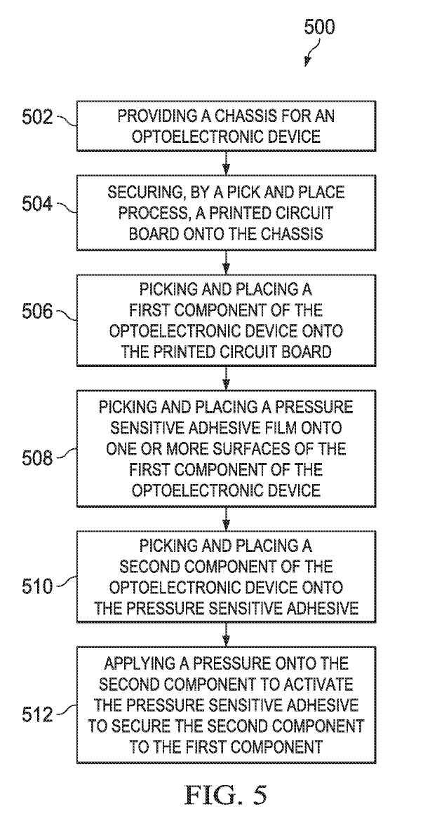

FIG. 5 is a process flow diagram 500 for assembling an optoelectronic device with a pressure sensitive adhesive film in accordance with embodiments of the present disclosure. The assembly procedure can be performed by a pick and place processing technology, such as a surface mount technology process. An optoelectronic device chassis can be provided (502). The optoelectronic device chassis can be similar to chassis 102 of FIG. 1. A printed circuit board (PCB) can be placed and secured onto the chassis (504). A first component of the optoelectronic device can be placed and secured onto the PCB (506). Though not explicitly discussed, it is understood that the process can include picking and placing one or more optoelectronic components within the first component. For example, if the first component is a base of a photodetector, the process can also include picking and placing an avalanche photodiode (such as APD 208) and a lens 206 onto the APD 208. The lens 206 can also be secured to the APD 208 using the picking and placing of a pressure sensitive adhesive (PSA) film.

A PSA film can be placed onto one or more surfaces of the first component (508). A second component of the optoelectronic device can be placed onto the PSA film (510). A pressure can be applied to the second component to activate the PSA film and to secure the second component to the first component (512).

The process of FIG. 5 can be performed for each component of the optoelectronic device that is secured using an adhesive. Noteworthy is that the process can exclude a thermal curing step for activating the adhesive.

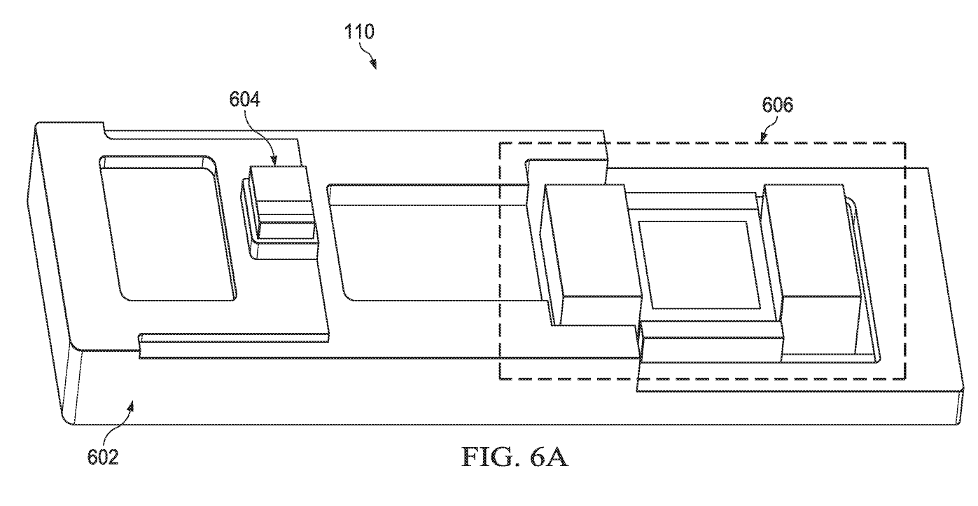

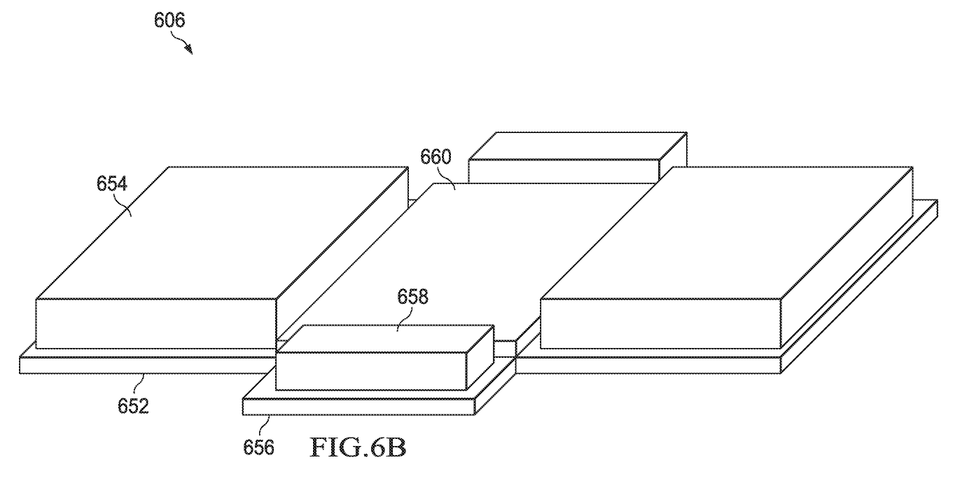

FIG. 6A is a schematic diagram of an optical projector 110 in accordance with embodiments of the present disclosure. The optical projector 110 can be similar to that shown in FIG. 1. The optical projector 110 includes a projector housing 602, a laser diode 604, and a sensor unit 606. The sensor unit 606 is shown as an inset in FIG. 6B. FIG. 6B is a schematic diagram of a sensor in accordance with embodiments of the present disclosure. The sensor unit 606 can include a MEMS-based sensor 660 that uses permanent magnets to provide static magnetic fields. The permanent magnets are shown as permanent magnet 654 and permanent magnet 658, for example. Permanent magnet 654 can be secured to the projector housing 602 using a pressure sensitive adhesive 652. Permanent magnet 658 can be secured to the projector housing 602 using a pressure sensitive adhesive 656.

Pressure sensitive adhesives (PSAs) 652 and 656 can include a filler that promotes magnetic conduction, such as magnetic additives. PSA 652 and 656 can include magnetic additives can be used to facilitate predicted static magnetic field strength and direction, while also securing the permanent magnetic elements to the projector housing 602. The PSA can be a templated PSA film that is picked-and-placed onto the projector housing 602. The permanent magnets 654 and 658 can be placed onto the PSA, and the PSA can be activated through an applied pressure. In embodiments, the PSA can be placed onto the magnets, and the magnets can be secured to the projector housing 602 with the PSA side down. Examples of magnetic additives include, but are not limited to, magnetite, ferrit, Sendust (FeAlSi), as well as other magnetic additives.

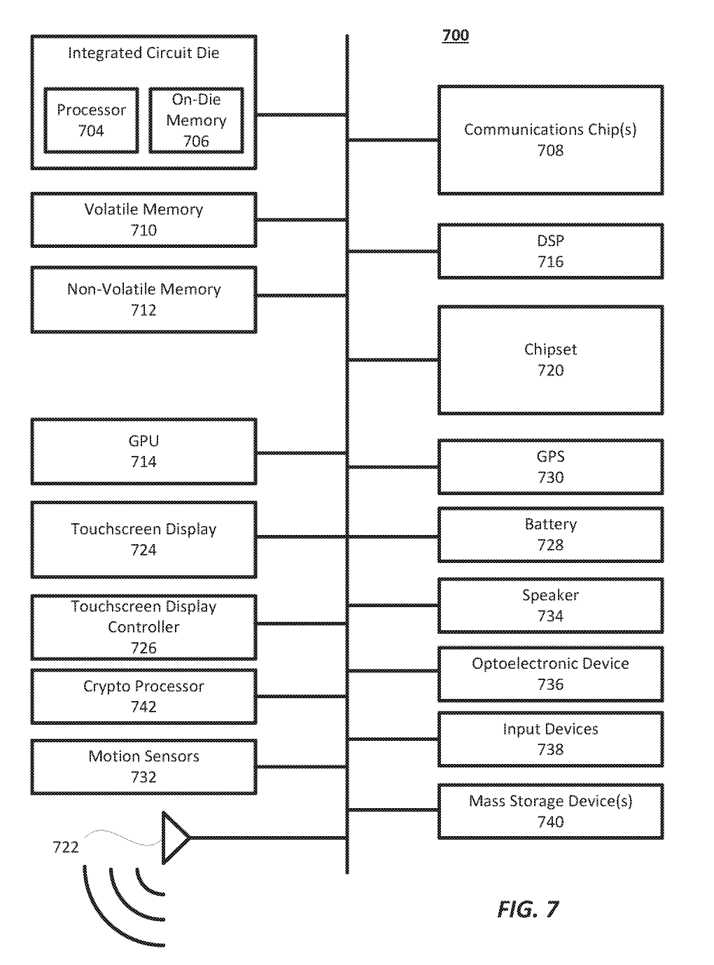

FIG. 7 illustrates a computing device 700 in accordance with one embodiment of the disclosure. The computing device 700 may include a number of components. In one embodiment, these components are attached to one or more motherboards. In an alternate embodiment, some or all of these components are fabricated onto a single system-on-a-chip (SoC) die. The components in the computing device 700 include, but are not limited to, an integrated circuit die 702 and at least one communications logic unit 708. In some implementations, the communications logic unit 708 is fabricated within the integrated circuit die 702 while in other implementations the communications logic unit 708 is fabricated in a separate integrated circuit chip that may be bonded to a substrate or motherboard that is shared with or electronically coupled to the integrated circuit die 702. The integrated circuit die 702 may include a CPU 704 as well as on-die memory 706, often used as cache memory, that can be provided by technologies such as embedded DRAM (eDRAM) or spin-transfer torque memory (STTM or STT-MRAM).

Computing device 700 may include other components that may or may not be physically and electrically coupled to the motherboard or fabricated within an SoC die. These other components include, but are not limited to, volatile memory 710 (e.g., DRAM), non-volatile memory 712 (e.g., ROM or flash memory), a graphics processing unit 714 (GPU), a digital signal processor 716, a crypto processor 742 (a specialized processor that executes cryptographic algorithms within hardware), a chipset 720, an antenna 722, a display or a touchscreen display 724, a touchscreen controller 726, a battery 728 or other power source, a power amplifier (not shown), a voltage regulator (not shown), a global positioning system (GPS) device 730, a motion coprocessor or sensors 732 (that may include an accelerometer, a gyroscope, and a compass), a speaker 734, a camera 736, user input devices 738 (such as a keyboard, mouse, stylus, and touchpad), and a mass storage device 740 (such as hard disk drive, compact disk (CD), digital versatile disk (DVD), and so forth).

The communications logic unit 708 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communications logic unit 708 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communications logic units 708. For instance, a first communications logic unit may be dedicated to shorter range wireless communications such as Wi-Fi and Bluetooth and a second communications logic unit may be dedicated to longer range wireless communications such as GPS, EDGE, GPRS, CDMA, WiMAX, LTE, Ev-DO, and others.

The processor 704 of the computing device 700 includes one or more devices, such as transistors or metal interconnects, that are formed in accordance with embodiments of the disclosure. For example, the processor 704 can include an image signal processor (ISP) and/or one or more application specific integrated circuits (ASICs). The term “processor” may refer to any device or portion of a device that processes electronic data from registers and/or memory to transform that electronic data into other electronic data that may be stored in registers and/or memory.

In various embodiments, the computing device 700 may be a laptop computer, a netbook computer, a notebook computer, an ultrabook computer, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 700 may be any other electronic device that processes data.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

The relative sizes of features shown in the figures are not drawn to scale.

The following paragraphs provide examples of various ones of the embodiments disclosed herein.

Example 1 is an optoelectronic device that can include a first component of the optoelectronic device; and a second component of the optoelectronic device secured to the first component of the optoelectronic device by a pressure sensitive adhesive (PSA) film.

Example 2 may include the subject matter of example 1, wherein the first component comprises a printed circuit board of the optoelectronic device; and the second component comprises an electromagnetic interference/radio frequency interference (EMI/RFI) shield.

Example 3 may include the subject matter of any of examples 1-2, wherein the PSA film comprises a conductive additive.

Example 4 may include the subject matter of example 3, wherein the conductive additive comprises one or more of a metallic powder or metallic flakes.

Example 5 may include the subject matter of example 4, wherein the conductive additive comprises one or more of copper, silver, nickel, or aluminum.

Example 6 may include the subject matter of any of examples 1-5, wherein the PSA film comprises an additive that promotes electromagnetic interference (EMI) shielding.

Example 7 may include the subject matter of example 6, wherein the additive comprises one or more of nickel, graphite, or carbon fiber.

Example 8 may include the subject matter of any of examples 1-7, wherein the first component comprises an infrared filter and the second component comprises an electromagnetic interference (EMI) shield, the EMI shield comprising an aperture, the infrared filter covering the aperture, the PSA film surrounding the aperture.

Example 9 may include the subject matter of any of examples 1-8, wherein the first component comprises an optoelectronic device chassis; the second component comprises a magnetic element; and wherein the PSA film comprises a magnetically conductive additive.

Example 10 may include the subject matter of example 9, wherein the magnetically conductive additive comprises one or more of magnetite, ferrite, or Sendust (AlFeSi).

Example 11 may include the subject matter of any of examples 1-10, wherein the first component comprises a base of the optoelectronic device; the second component comprises one or more of a laser or a laser driver; and the PSA film comprises a thermally conductive additive.

Example 12 may include the subject matter of example 11, wherein the thermally conductive additive comprises copper, silver, aluminum, zinc oxide, boron nitride, aluminum oxide, or nanometer-scale particles.

Example 13 may include the subject matter of any of examples 1-12, wherein the PSA film comprises a double-sided adhesive.

Example 14 is a method for assembling an optoelectronic device, the method including providing a first component of an optoelectrical device; placing a pressure sensitive adhesive (PSA) film onto a surface of the first component; placing a second component of the optoelectrical device onto the PSA film; and applying a pressure to the second component to activate the PSA film and secure the second component to the first component.

Example 15 may include the subject matter of example 14, further comprising providing a chassis of an optoelectronic device; placing a printed circuit board onto the chassis; and placing the first component onto the printed circuit board.

Example 16 may include the subject matter of any of examples, wherein the first component comprises a printed circuit board of the optoelectronic device; and the second component comprises an electromagnetic interference or radio frequency interference shield.

Example 17 may include the subject matter of example 16, wherein the PSA film comprises a conductive additive.

Example 18 may include the subject matter of example 17, wherein the conductive additive comprises one or more of a metallic powder or metallic flakes.

Example 19 may include the subject matter of example 18, wherein the conductive additive comprises one or more of copper, silver, nickel, or aluminum.

Example 20 may include the subject matter of any of examples 16-19, wherein the PSA film comprises an additive that promotes electromagnetic interference (EMI) shielding.

Example 21 may include the subject matter of example 20, wherein the additive comprises one or more of nickel, graphite, or carbon fiber.

Example 22 may include the subject matter of any of examples 14-21, wherein the first component comprises an infrared filter and the second component comprises an electromagnetic interference/radio frequency interference (EMI/RFI) shield, the EMI/RFI shield comprising an aperture, the method comprising placing the PSA film onto a surface of the EMI/RFI shield surrounding the aperture, and placing the infrared filter onto the EMI/RFI shield at a location covering the aperture.

Example 23 may include the subject matter of any of examples 14-22, wherein the first component comprises an optoelectronic device chassis; the second component comprises a magnetic element; and wherein the PSA film comprises a magnetically conductive additive.

Example 24 may include the subject matter of example 23, wherein the magnetically conductive additive comprises one or more of magnetite, ferrite, or Sendust (AlFeSi).

Example 25 may include the subject matter of any of examples 14-24, wherein the first component comprises a base of the optoelectronic device; the second component comprises one or more of a laser or a laser driver; and the PSA film comprises a thermally conductive additive.

Example 26 may include the subject matter of example 25, wherein the base comprises one of a printed circuit board of a chassis of the optoelectronic device.

Example 27 may include the subject matter of any of examples 25-26 wherein the thermally conductive additive comprises copper, silver, aluminum, zinc oxide, boron nitride, aluminum oxide, or nanometer-scale particles.

Example 28 is a computing device comprising one or more application specific integrated circuits; a light emitter; and a photodetector. The photodetector can include a first component of the optoelectronic device; a second component of the optoelectronic device secured to the first component of the optoelectronic device by the PSA film; and a pressure sensitive adhesive between the first component and the second component, the pressure sensitive adhesive causing the first component to adhere to the second component.

Example 29 may include the subject matter of example 28, wherein the first component comprises an electromagnetic interference/radio frequency interference (EMI/RFI) shield, and the second component comprises an infrared (IR) filter, wherein the EMI/RFI shield comprises an aperture for permitting light to enter the photodetector, the PSA film residing on the EMI/RFI shield and surrounding the aperture, and the IR filter residing on the PSA film at a location covering the aperture.

Example 30 may include the subject matter of example 28, wherein the computing device comprises an electromagnetic interference/radio frequency interference (EMI/RFI) shield, and a printed circuit board (PCB), the EMI/RFI shield secured to the PCB by a conductive PSA film.

What is claimed is:

1. An optoelectronic device comprising:
a first component of the optoelectronic device; and
a second component of the optoelectronic device secured to the first component of the optoelectronic device by a pressure sensitive adhesive (PSA) film.

2. The optoelectronic device of claim 1, wherein:
the first component comprises a printed circuit board of the optoelectronic device; and
the second component comprises an electromagnetic interference/radio frequency interference (EMI/RFI) shield.

3. The optoelectronic device of claim 2, wherein the PSA film comprises a conductive additive.

4. The optoelectronic device of claim 3, wherein the conductive additive comprises one or more of a metallic powder or metallic flakes.

5. The optoelectronic device of claim 4, wherein the conductive additive comprises one or more of copper, silver, nickel, or aluminum.

6. The optoelectronic device of claim 2, wherein the PSA film comprises an additive that promotes electromagnetic interference (EMI) shielding.

7. The optoelectronic device of claim 6, wherein the additive comprises one or more of nickel, graphite, or carbon fiber.

8. The optoelectronic device of claim 1, wherein the first component comprises an infrared filter and the second component comprises an electromagnetic interference (EMI) shield, the EMI shield comprising an aperture, the infrared filter covering the aperture, the PSA film surrounding the aperture.

9. The optoelectronic device of claim 1, wherein:
the first component comprises an optoelectronic device chassis;
the second component comprises a magnetic element; and
wherein the PSA film comprises a magnetically conductive additive.

10. The optoelectronic device of claim 9, wherein the magnetically conductive additive comprises one or more of magnetite, ferrite, or Sendust (AlFeSi).

11. The optoelectronic device of claim 1, wherein:
the first component comprises a base of the optoelectronic device;
the second component comprises one or more of a laser or a laser driver; and
the PSA film comprises a thermally conductive additive.

12. The optoelectronic device of claim 11, wherein the thermally conductive additive comprises copper, silver, aluminum, zinc oxide, boron nitride, aluminum oxide, or nanometer-scale particles.

13. The optoelectronic device of claim 1, wherein the PSA film comprises a double-sided adhesive.

14. A method for assembling an optoelectronic device, the method comprising:
providing a first component of an optoelectrical device;
placing a pressure sensitive adhesive (PSA) film onto a surface of the first component;
placing a second component of the optoelectrical device onto the PSA film; and
applying a pressure to the second component to activate the PSA film and secure the second component to the first component.

15. The method of claim 14, further comprising:
providing a chassis of an optoelectronic device;
placing a printed circuit board onto the chassis; and
placing the first component onto the printed circuit board.

16. The method of claim 14, wherein:
the first component comprises a printed circuit board of the optoelectronic device; and
the second component comprises an electromagnetic interference or radio frequency interference shield.

17. The method of claim 16, wherein the PSA film comprises a conductive additive, wherein the conductive additive comprises one or more of a metallic powder or metallic flakes.

18. The method of claim 17, wherein the conductive additive comprises one or more of copper, silver, nickel, or aluminum.

19. The method of claim 16, wherein the PSA film comprises an additive that promotes electromagnetic interference (EMI) shielding, wherein the additive comprises one or more of nickel, graphite, or carbon fiber.

20. The method of claim 14, wherein the first component comprises an infrared filter and the second component comprises an electromagnetic interference/radio frequency interference (EMI/RFI) shield, the EMI/RFI shield comprising an aperture,
the method comprising placing the PSA film onto a surface of the EMI/RFI shield surrounding the aperture, and placing the infrared filter onto the EMI/RFI shield at a location covering the aperture.

21. The method of claim 14, wherein:
the first component comprises an optoelectronic device chassis;
the second component comprises a magnetic element; and
wherein the PSA film comprises a magnetically conductive additive,
wherein the magnetically conductive additive comprises one or more of magnetite, ferrite, or Sendust (AlFeSi).

22. The method of claim 14, wherein:
the first component comprises one of a printed circuit board of a chassis of the optoelectronic device of the optoelectronic device;
the second component comprises one or more of a laser or a laser driver; and
the PSA film comprises a thermally conductive additive,
wherein the thermally conductive additive comprises copper, silver, aluminum, zinc oxide, boron nitride, aluminum oxide, or nanometer-scale particles.

23. A computing device comprising:
one or more application specific integrated circuits;
a light emitter; and
a photodetector, the photodetector comprising:
a first component of the optoelectronic device;
a second component of the optoelectronic device secured to the first component of the optoelectronic device by the PSA film; and
a pressure sensitive adhesive between the first component and the second component, the pressure sensitive adhesive causing the first component to adhere to the second component.

24. The computing device of claim 23, wherein the first component comprises an electromagnetic interference/radio frequency interference (EMI/RFI) shield, and the second component comprises an infrared (IR) filter, wherein the EMI/RFI shield comprises an aperture for permitting light to enter the photodetector, the PSA film residing on the EMI/RFI shield and surrounding the aperture, and the IR filter residing on the PSA film at a location covering the aperture.

25. The computing device of claim 23, wherein the computing device comprises an electromagnetic interference/radio frequency interference (EMI/RFI) shield, and a printed circuit board (PCB), the EMI/RFI shield secured to the PCB by a conductive PSA film.
